(19) United States
(12) Patent Application Publication
(10) Pub. No.: US 2015/0260766 A1
(43) Pub. Date: Sep. 17, 2015

(54) SEMICONDUCTOR DEVICE

(71) Applicants: HUBERT BODE, HAAR (DE); MATHIEU GAUTHIER LESBATS, MUNICH (DE); ANDREAS JOHANN ROTH, GUENZENHAUSEN (DE)

(72) Inventors: HUBERT BODE, HAAR (DE); MATHIEU GAUTHIER LESBATS, MUNICH (DE); ANDREAS JOHANN ROTH, GUENZENHAUSEN (DE)

(73) Assignee: FREESCALE SEMICONDUCTOR, INC., Austin, TX (US)

(21) Appl. No.: 14/214,796

(22) Filed: Mar. 15, 2014

(51) Int. Cl. G01R 19/165; G01R 1/36

(52) U.S. Cl. CPC G01R 19/16566; G01R 1/36

(57) ABSTRACT

A semiconductor device, comprising a substrate and an electronic circuit formed thereon is described. The substrate is susceptible to conducting a substrate current. The semiconductor device further comprises a substrate current sensor, which comprises a sensing line for sensing the potential at a charge collecting region; a supply node; and a current source connected between the supply node and the charge collecting region. The current source is arranged to inject a stationary current into the charge collecting region when the potential at the charge collecting region is below the supply potential. The sensing line comprises a monoflop, which is arranged to assume an unstable state when the potential at its input has exceeded a threshold and to return to a stable state when the potential at its input has remained below the threshold for at least a time period.

### FIELD OF THE INVENTION

This invention relates to a semiconductor device.

### BACKGROUND OF THE INVENTION

FIG. 1 schematically shows an example of a semiconductor device 10, e.g., a CMOS device. The semiconductor device 10 comprises a substrate 12 on which an electronic circuit 14 is provided. The electronic circuit 14 may be formed at least partly on or in the substrate. For example, the electronic circuit 14 may comprise components such as diodes or transistors comprising doped regions of the substrate 16 and suitably interconnected by metal conductors on or in the substrate. In the example, the electronic circuit 14 is a micro controller unit (MCU). However, it may be any other kind of electronic circuit. The electronic circuit 14 may comprise multiple contact pads 16, e.g., two or more contact pads, for connecting the electronic circuit 14 to an external device (not shown).

A problem that may be encountered with a semiconductor device of this kind is that a spurious electrical current may temporarily be injected into the substrate 12 via the pads 16. Current injection may, for example, be caused by radio frequency perturbations in an environment of the semiconductor device 10, or by perturbations generated or transmitted by an external device connected to the electronic circuit 14 via the contact pads 16. At least part of the injected current may flow through regions of the substrate that are not part of the electronic circuit 14 and may therefore cause various undesired effects such as voltage surges and state transitions. The injected current may notably pass through isolating regions of the substrate 12, e.g., through regions intended to isolate diodes, transistors, or other components of the circuit from each other.

In one scenario, negative charge carriers, e.g., electrons, are injected via the pads 16 and accumulate at a negative well, e.g., a negatively doped region, of the substrate 12, thus temporarily lowering the electrical potential at the negative well. In another scenario, negative carriers are injected via a subset of pads, traverse the substrate and leave the substrate via another subset of pads. In both scenarios, the injected current may have undesired effects.

In order to protect sensitive parts of the electronic circuit 14 against injected currents, a guard ring 18 may be provided, as proposed, for example, in U.S. Pat. No. 5,168,340 (Nishimura). The guard ring 18 may surround the electronic circuit 14 or a sensitive region thereof, or it may extend along a major portion of a contour surrounding the sensitive region. The guard ring 18 may, however, be insufficient when the magnitude of the injected current exceeds a critical magnitude. Furthermore, it may be desirable to produce substrates which do not require a guard ring.

U.S. Pat. No. 8,315,026 B2 (Roth) proposes integrating a substrate current sensor 20 in the substrate 12, for sensing an injected substrate current. The substrate current sensor 20 may, for example, be connected to a current meter 22 for generating a signal 24 indicative of a magnitude of the substrate current. The signal 24 may be provided to the electronic circuit 14, thus enabling the electronic circuit 14 to respond to the substrate current in a suitable manner, for instance, by switching to a safe mode. The substrate current sensor 20 and the meter 22 may be part of the electronic circuit 14. Notably, the meter 22 may be arranged on or in the substrate 12 and be integrated in the electronic circuit 14, although this is not shown in the figure.

FIG. 2 schematically shows a cross section of an example of a substrate 12 as may be included in, e.g., the semiconductor device 10 shown in FIG. 1. A similar substrate has been described in greater detail in the above mentioned U.S. Pat. No. 8,315,026 B2 by Roth et al. It may comprise, for example, an injecting device 26, e.g., a NMOS field effect transistor (FET), the substrate current sensor 20, the guard ring 18, and a sensitive device 28, e.g., a PMOS FET. In a variant of the example, the guard ring 18 may be absent.

In the event of, e.g., an external perturbation, negative carriers may be injected into the substrate 12 via the injecting device 26 and be attracted by the sensitive device 28. In the example, the substrate is of a p type, and the sensitive device 28 comprises a negative well (n well) which may attract the negative carriers. A substrate current from the sensitive device 28 to the injecting device 26 through the substrate 12 may thus occur. The sensitive device 28 may thus be charged negative, which may be undesired. The substrate current may be supressed or reduced by the guard ring 18. The attraction of negative carriers by the negative well is an example of a bipolar coupling effect. In the case of an n-doped substrate (not shown), positive carriers (holes) may be attracted by a p-well.

Capacitive coupling of currents is another effect that may be observed in a semiconductor substrate. In one example, an aggressor pumps current into and out of the substrate through its capacitance to the substrate. As the resistance of the substrate is finite, this may modulate the substrate potential and a component located on or in the substrate (referred to as a victim) may then experience an exchange current through its own capacitance to the substrate. This can cause a variation of the potential into either direction on the victim's side.

An example of an embodiment of the sensor 20 and an example of a mode of operation of the sensor 20 are described in reference to FIGS. 3, 4, and 5.

As schematically illustrated in FIG. 3, the substrate current sensor 20 may be arranged to attract carriers injected into the substrate 12, e.g., negative carriers. To this end, the substrate current sensor 20 may comprise a charge collecting region 30 for attracting the carriers, e.g., a negative well 30 for attracting the negative carriers. Furthermore, the sensor 20 may comprise a current source 32 for removing carriers from the charge collecting region 30; e.g., for removing a quantity of negative carriers from the negative well 30.

As schematically illustrated in FIG. 4, the current source 32 may be connected to the negative well 30 and be arranged to produce a reference current I_{ref} (also referred to herein as the threshold current) from a supply node 34 to the negative well 30, thus charging the negative well 30 and raising the potential at the negative well 30 to a sensor potential Vₛₑₙₛₒᵣ which may be the potential at the supply node 34. Thus, a current comparator may be formed. When the injected current I_{injected} exceeds the reference current I_{ref}, the negative well 30 may decharge and its potential may fall accordingly. The current source is not an ideal current source. Rather, it is an implementable current source. It may sustain the reference current I_{ref} only as long as the potential at the negative well is below a supply level of the current source, e.g, below the potential provided by the supply node 34.

A flip flop 38, e.g., a RS flip flop, may be connected, e.g., via an inverter 36, to the negative well 30 so as to detect the voltage drop at the negative well 30 that may be caused by the injected current I_{injected}. In the example, when the injected current is less than the reference current of the current source 32, the input of the inverter 36 is high and the set input (S input) of the flip flop 38 is low. When the injected current exceeds the reference current I_{ref}, the input of the inverter 36 is pulled low and the S input of the flip flop 38 is driven high, thus setting the flip flop 38. The flip flop 38 may thus indicate that the injected current I_{injected} has exceeded the reference current I_{ref}. The Q output of the flip flop 38 may be connected, for example, to a control unit (not shown). The control unit may be arranged to set the electronic circuit 14 into an appropriate operating mode or into an appropriate state in dependence of the state of the flip flop 38. The sensor 20 as well as the control unit may be integrated in the electronic circuit 14.

FIG. 5 schematically illustrates an example in which the sensitive device 28 is an NMOS transistor with a deep negatively doped implant, e.g., a UHV NMOS transistor. Here, “deep” refers to the vertical dimension of the implant. The implant may be deep in the sense that it extends deep into the substrate. The NMOS transistor 28 comprises a source 40, a drain 42, and a gate 46. The drain 42 may comprise a deep negatively doped implant 48. The NMOS transistor may further comprise a shallow trench isolation STI. The implant 48 may render the drain 42 particularly susceptible to collecting negative carriers from the substrate 12. This may be due to the deepness of the implant 48 and to the fact that the implant is not shielded by the shallow trench isolation STI or other isolation techniques of a given semiconductor process.

### SUMMARY OF THE INVENTION

The present invention provides a semiconductor device as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. Elements in the figures are illustrated for simplicity and clarity and have not necessarily been drawn to scale.

FIG. 1 schematically shows a top view of an example of an embodiment of a semiconductor device.

FIG. 2 schematically shows a sectional view of an example of an embodiment of a semiconductor device.

FIG. 3 schematically shows a close-up of FIG. 2.

FIG. 4 schematically shows an example of an embodiment of a substrate current sensor.

FIG. 5 schematically shows an example of an embodiment of a NMOS transistor.

FIG. 6 schematically shows an example of a semiconductor device.

FIG. 7 schematically shows another example of a semiconductor device.

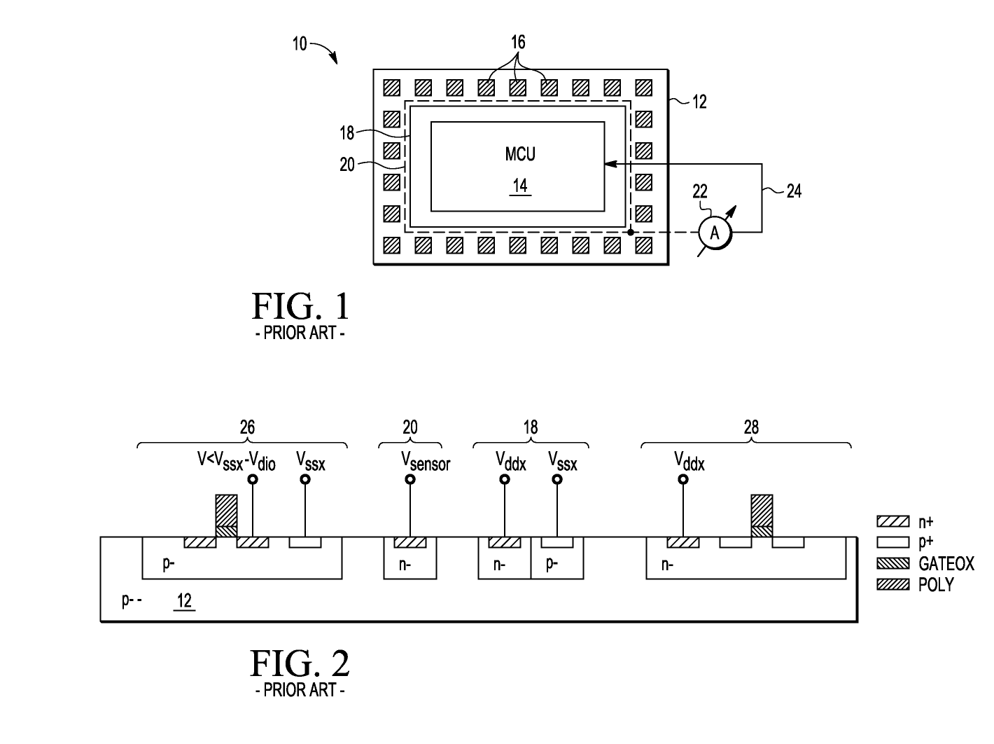

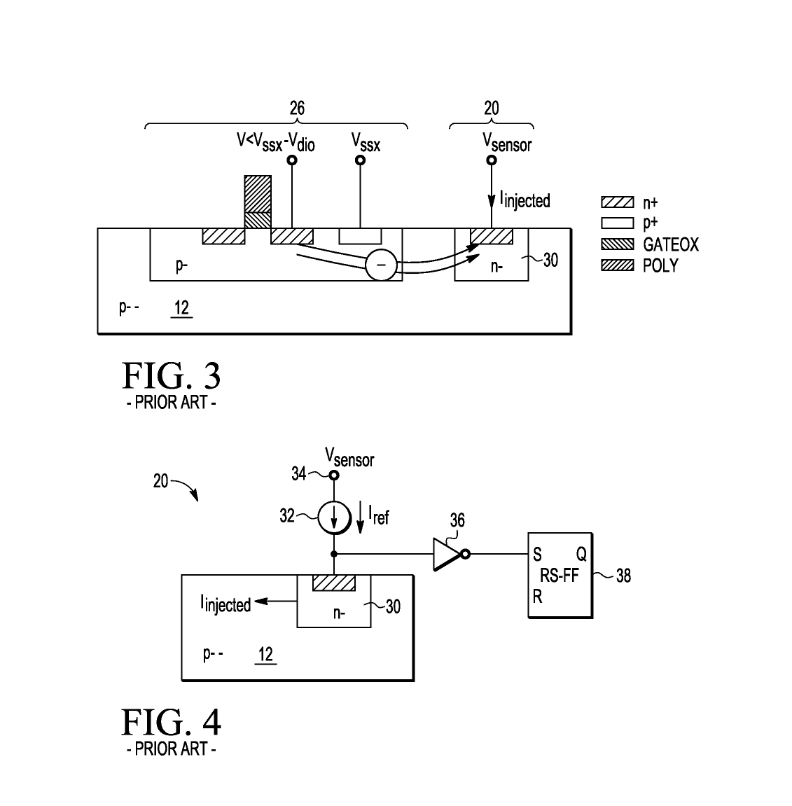

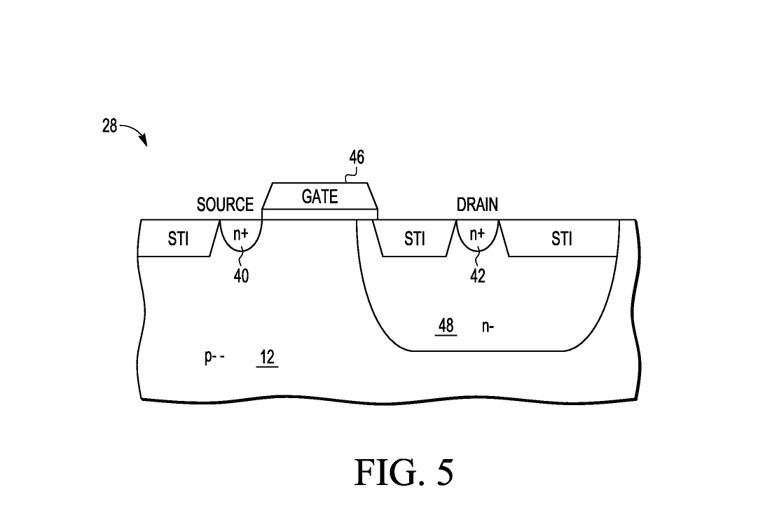

### DETAILED DESCRIPTION OF THE PREFERRED EMBODIMENTS

As mentioned above, there may be at least one of two coupling effects, each affecting the sensor as well as the nodes to be protected.

One effect is bipolar coupling where foreign (victim) negative diffusions may be dragged down through parasitic npn devices (in the case of p-doped substrate materials) or parasitic pnp devices (in the case of n-doped substrate materials).

The other effect is capacitive coupling. For example, when an input toggles rapidly, with stray capacitance into the substrate, the substrate potential, due to its finite resistance, may deviate from a constant potential applied by, e.g., substrate pickups. Such victims with stray capacitance into the substrate may suffer an exchange current which can negatively influence the circuit. The exchange current, that is, a particular kind of substrate current, may have a duration that is considerably shorter than a substrate current caused by bipolar coupling. In view of this, examples of a substrate current sensor with an adapted sensing line are described below.

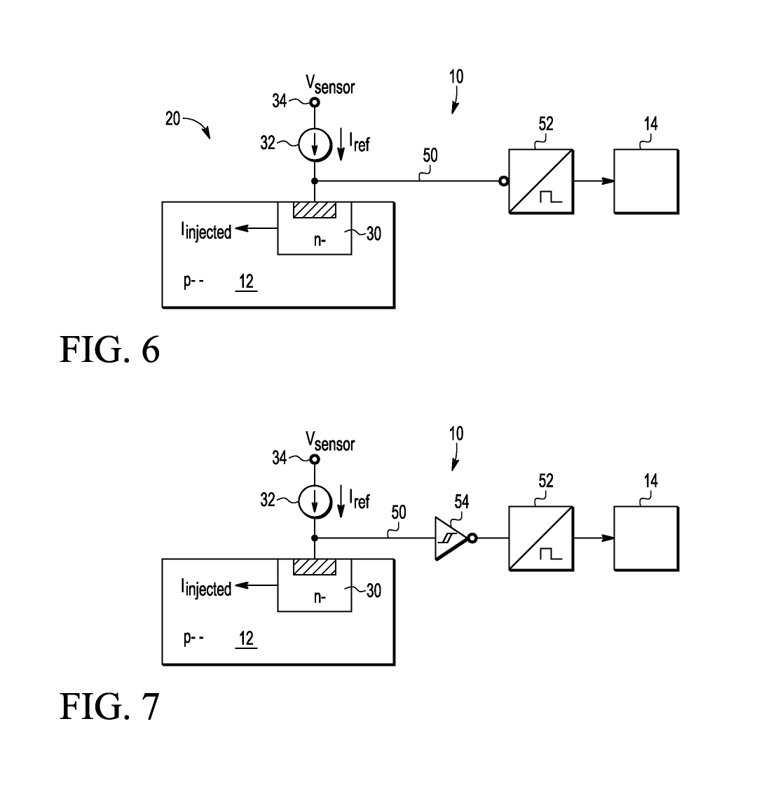

FIG. 6 schematically shows an example of a semiconductor device 10 comprising a substrate 12 and an electronic circuit 14. The electronic circuit 14 may be formed at least partly on or in the substrate 12, although this is not shown in the figure. The substrate 12 may be susceptible to conducting a substrate current, which may be a variable spurious electrical current. The semiconductor device 10 comprises a substrate current sensor 20 for sensing the substrate current. The substrate current sensor 20 may comprise a sensing line 50, a supply node 34, and a current source 32. The sensing line 50 may be connected to a charge collecting region 30 of the substrate 12 so as to sense the potential at the charge collecting region 30. The charge collecting region may be a doped region of the substrate 12. For example, the substrate 12 may be of a p-type and the charge collecting region 30 may be of an n-type, or vice versa. The supply node 34 may be arranged to provide a supply potential. For example, the supply node 34 may be connected or connectable to a direct current (DC) voltage provider. The current source 32 may be connected between the supply node 34 and the charge collecting region 30. In operation, the current source 32 may inject a stationary current I_REF into the charge collecting region 30 as a reference current when the potential as long as the charge collecting region 30 is below the supply potential.

The sensing line 50 comprises a monoflop 52. The monoflop 52 has a stable state, an unstable state, a monoflop threshold, a monoflop time, an input and an output. In operation, the monoflop assumes its unstable state when its input potential exceeds the monoflop threshold. The monoflop returns to its stable state when its input potential has remained below the monoflop threshold for at least the length of the monoflop time. The monoflop may thus pass to its unstable state virtually immediately when the potential at its input exceeds the monoflop threshold but return to its stable state only after a set delay, namely after lapse of the monoflop time, when the monoflop input potential has dropped below the monoflop threshold. In other words, the monoflop 52 may produce a bi-level output signal which generally correlates with the detected substrate current, with the peculiarity that the monoflop does not return immediately to its stable state when the substrate current has become less than the reference current I_REF. The monoflop time may, for example, be a time between 100 nanoseconds and fifty milliseconds. This may be a good compromise between detection efficiency and power consumption.

Notably, a succession of short transients of the substrate current may be signalled by the monoflop 52 as one single substrate current transient with a duration of the succession of short transients. More specifically, when the time gap between two transients of the substrate current is less than the monoflop time, these two transients may be signalled by the monoflop 52 as one single transient. This can be notably advantageous when the electronic circuit 14 is arranged to respond to a transient, as signalled by the monoflop 52, by initiating a protective action. For example, a burst of short substrate current transients may occur in the substrate 12. That is, there may be two or more successive substrate current transients separated from each other by time gaps shorter than the monoflop time. In this case, the monoflop 52 may remain in its unstable state and its output may be, e.g., high during the entire burst, thus ensuring that a protective action initiated by the electronic circuit in response to a rising edge of the monoflop output signal remains effective during the entire burst.

The electronic 14 may be arranged to respond in real-time to the output from the sensing line 50. In one example, the electronic circuit 14 may be arranged to reduce an internal impedance of the electronic circuit 14 temporarily when the output of the signal line 52 is high. The electronic circuit 14 may thus become more robust against the substrate current, at the expense of a temporarily increased power consumption.

It is noted that the delay (response delay) between the response by the electronic circuit 14 and a transient of the substrate current may be relatively long. The response delay may notably be longer than the duration of the transient. In this case the response by the electronic circuit 14 may become effective only when the transient has already passed. While a single transient of the substrate current may be unlikely to affect the electronic circuit seriously, a burst of transients may be detrimental. Provision of the monoflop 52 in the sensing line 50 may enable the electronic circuit 14 to respond to a transient in an adequate manner, namely to remain in a robust state at least for the duration of the monoflop time. For instance, the electronic circuit 14 may have a normal mode and a robust mode and may be arranged to be in the normal mode when the monoflop is in its stable state and in the robust mode when the monoflop is in its unstable state. For example, the electronic circuit 14 may have an electrical resistance which is lower in the robust mode than in the normal mode.

In the example shown in FIG. 7, the sensing line 50 further comprises an inverter 54. The input of the monoflop 52 may be connected to the charge collecting region 30 via the inverter 54. The inverter may have a hysteresis. This may be beneficial to provide a more stable output signal by the sensing line 50. The inverter 54 may for example be a Schmitt trigger.

Even when the inverter 54 does not exhibit any substantial hysteresis, the inverter 54 may be beneficial as a intermediary component between the charge collecting region 30 and the input of the monoflop 52, e.g., in an implementation in which the potential at the charge collecting region 30 is in a range that is inconvenient for direct evaluation by the monoflop 52.

In the foregoing specification, the invention has been described with reference to specific examples of embodiments of the invention. It will, however, be evident that various modifications and changes may be made therein without departing from the broader spirit and scope of the invention as set forth in the appended claims.

For example, the connections may be an type of connection suitable to transfer signals from or to the respective nodes, units or devices, for example, via intermediate devices. Accordingly, unless implied or stated otherwise the connections may, for example, be direct connections or indirect connections.

The semiconductor substrate described herein can be any semiconductor material or combinations of materials, such as gallium arsenide, silicon germanium, silicon, monocrystalline silicon, the like, and combinations of the above, possibly with the exception of silicon-on-insulator (SOI). In fact, the above described effects that may generate a spurious substrate current may be absent or less pronounced in SOI materials.

The terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Each signal described herein may be designed as positive or negative logic, where negative logic can be indicated by a bar over the signal name or an asterisk (*) following the name. In the case of a negative logic signal, the signal is active low where the logically true state corresponds to a logic level zero. In the case of a positive logic signal, the signal is active high where the logically true state corresponds to a logic level one. Any of the signals described herein can be designed as either negative or positive logic signals. Therefore, in alternate embodiments, those signals described as positive logic signals may be implemented as negative logic signals, and those signals described as negative logic signals may be implemented as positive logic signals.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention has been described with respect to specific conductivity types or polarity of potentials, conductivity types and polarities of potentials may be reversed.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or an limits any particular claim containing such introduced claim element to inventions containing only one such element, even when the same claim includes the introductory phrases one or more or at least one and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage.

1. A semiconductor device, comprising a substrate and an electronic circuit formed at least partly on or in the substrate, wherein the substrate is susceptible to conducting a substrate current, which is a variable spurious electrical current, and wherein the semiconductor device further comprises a substrate current sensor for sensing the substrate current, wherein the substrate current sensor comprises:
a sensing line connected to a charge collecting region of the substrate, for sensing the potential at the charge collecting region;
a supply node for providing a supply potential;
a current source connected between the supply node and the charge collecting region, wherein the current source is arranged to inject a stationary current into the charge collecting region when the potential at the charge collecting region is below the supply potential;
wherein the sensing line comprises a monoflop, the monoflop having a stable state, an unstable state, a monoflop threshold, a monoflop time, an input and an output, and wherein the monoflop is arranged to assume its unstable state when the potential at its input has exceeded the monoflop threshold and to return to its stable state when the potential at its input has remained below the monoflop threshold for at least the length of the monoflop time.

2. The semiconductor device, wherein the sensing line further comprises an inverter, wherein the input of the monoflop is connected to the charge collecting region via the inverter.

3. The semiconductor device of claim 2, wherein the inverter has a hysteresis.

4. The semiconductor device of claim 3, wherein the inverter is a Schmitt trigger.

5. The semiconductor device of claim 1, wherein the charge collecting region is a doped region of the substrate.

6. The semiconductor device of claim 5, where the substrate is of a p type and the charge collecting region is of an n type, or vice versa.

7. The semiconductor device of claim 1, wherein the monoflop time is a time between 100 nanoseconds and fifty milliseconds.

8. The semiconductor device of claim 1, wherein the electronic circuit has a normal mode and a robust mode and is arranged to be in the normal mode when the monoflop is in its stable state and in the robust mode when the monoflop is in its unstable state.

9. The semiconductor device of claim 8, wherein the electronic circuit has an electrical resistance which is lower in the robust mode than in the normal mode.
